(19) United States
(12) Patent Application Publication
(10) Pub. No.: US 2011/0023950 A1
(43) Pub. Date: Feb. 3, 2011

(54) PHOTOVOLTAIC CELL SUBSTRATE

(75) Inventors: Je Choon Ryoo, ChungCheongNam-Do (KR); Dong Woo Kim, ChungCheongNam-Do (KR); Seo Hyun Kim, ChungCheongNam-Do (KR)

Correspondence Address: LERNER, DAVID, LITTENBERG,;KRUMHOLZ & MENTLIK, 600 SOUTH AVENUE WEST, WESTFIELD, NJ, 07090, US

(73) Assignee: SAMSUNG CORNING PRECISION MATERIALS CO., LTD., Gyeongsangbuk-do (KR)

(21) Appl. No.: 12/845,001

(22) Filed: Jul. 28, 2010

(30) Foreign Application Priority Data
Jul. 29, 2009 (KR) 10-2009-0069242

(51) Int. Cl. H01L 31/0288

(52) U.S. Cl. 136/255

(57) ABSTRACT

A photovoltaic cell substrate includes a transparent substrate, a transparent conductive film formed over the transparent substrate, the transparent conductive film made of a doped zinc oxide, a protective film formed over the transparent conductive film, and an elution-preventive film formed between the transparent substrate and the transparent conductive film. The elution-preventive film prevents elution from inside the transparent substrate.

### CROSS REFERENCE TO RELATED APPLICATION

The present application claims priority from Korean Patent Application Number 10-2009-0069242 filed on Jul. 29, 2009, the entire contents of which application are incorporated herein for all purposes by this reference.

### BACKGROUND OF THE INVENTION

1. Field of the Invention

The present invention relates to a photovoltaic cell substrate.

2. Description of Related Art

A photovoltaic cell is a key element in photovoltaic power generation, in which energy from sunlight is directly converted into electricity. Photovoltaic cells are applied in various fields, which include electrical and electronic appliances, the supply of electrical power to houses and buildings, and industrial power generation. The most basic photovoltaic cell has structure like a diode that has a pn junction. Photovoltaic cells can be categorized according to the material used in the light absorbing layer. Photovoltaic cells may be categorized into a silicon photovoltaic cell, which uses silicon as the light absorbing layer; a compound photovoltaic cell, which uses, for example, Copper Indium Selenide (CIS: CuInSe₂) or Cadmium Telluride (CdTe) as the light absorbing layer; a dye-sensitized photovoltaic cell, in which photosensitive dye, which excite electrons in response to the absorbing of visible light, are bonded to the surface of nano-particles of a porous layer; a stacked photovoltaic cell, in which, for example, a plurality of amorphous silicon layers are stacked on one another, etc. In addition, photovoltaic cells may be categorized into bulk photovoltaic cells (including single crystalline photovoltaic cells and polycrystalline photovoltaic cells) or thin film photovoltaic cells (including amorphous photovoltaic cells and polycrystalline photovoltaic cells).

At present, bulk photovoltaic cells which use polycrystalline silicon, occupy 90% or more of the whole market. However, the cost of using bulk photovoltaic cells for power generation is three to ten times as expensive as when using existing power generation techniques, such as thermal power generation technique, nuclear power generation technique, or hydraulic power generation technique. This is mainly attributable to the high cost of crystalline silicon and the high manufacturing cost of the crystalline silicon photovoltaic cell, which is complicated to manufacture. Therefore, in recent days, amorphous silicon (a-Si:H) and microcrystalline silicon (μc-Si:H) thin film photovoltaic cells are being actively studied and commercially distributed.

FIG. 1 is a cross-sectional view showing the structure of a photovoltaic cell using amorphous silicon as a light-absorbing layer in the related art.

As shown in the figure, the conventional amorphous silicon (e.g., a-Si:H) photovoltaic cell 110 includes a transparent substrate 111, a transparent conductive film 112, a p-type amorphous silicon (a-Si:H) layer 113, which is doped with a dopant, an i-type (intrinsic) amorphous silicon (a-Si:H) layer 114, which is not doped with a dopant, an n-type amorphous silicon (a-Si:H) layer 115, which is doped with a dopant, and a back reflector 116. In the i-type amorphous silicon (a-Si:H) layer 114, depletion occurs under the influence of the p-type and n-type amorphous silicon (a-Si:H) layers 113 and 115, thereby generating an electric field. An electron-hole pair created in the i-type amorphous silicon (a-Si:H) layer 114 in response to incident light (hν), is collected by the p-type amorphous silicon (a-Si:H) layer 113 and the n-type amorphous silicon (a-Si:H) layer 115 through the drift due to the internal electric field, thereby generating an electric current.

The microcrystalline silicon (μc-Si:H) is an intermediate material between single crystalline silicon and amorphous silicon, and has a crystal size ranging from tens to hundreds of nanometers. In the microcrystalline silicon, an amorphous phase is frequently present at the interface between crystals and, in most cases, carrier recombination occurs due to high defect density. The microcrystalline silicon (μc-Si:H) has an energy band gap of about 1.6 eV, which is substantially the same as that of the single crystalline silicon, and does not exhibit deterioration, which occurs in the amorphous silicon (a-Si:H) photovoltaic cell. The structure of the microcrystalline silicon (μc-Si:H) photovoltaic cell is very similar to that of the amorphous silicon (a-Si:H) photovoltaic cell, except for the light absorbing layer.

A single p-i-n junction thin film photovoltaic cell, which uses the amorphous silicon (a-Si:H) or the microcrystalline silicon (μc-Si:H) as the light absorbing layer, has many restrictions on its use in practice due to low light conversion efficiency. Therefore, a tandem photovoltaic cell or a triply stacked photovoltaic cell, which is fabricated by doubly or triply stacking the amorphous silicon (a-Si:H) or the microcrystalline silicon (μc-Si:H), is used, because it can raise open circuit voltage and improve light conversion efficiency by connecting the component photovoltaic cells in series.

FIG. 2 is a cross-sectional view showing the structure of a tandem photovoltaic cell of the related art.

As shown in the figure, the tandem photovoltaic cell 210 of the related art generally includes a transparent substrate 211, a transparent conductive film 212, a first pn junction layer 213, a tunneling pn junction layer 214, a second pn junction layer 215, and a back reflector 216.

In the tandem photovoltaic cell 210 of the related art, the first pn junction layer 213, having a predetermined band gap (e.g., E_{g}=1.9 eV), is disposed above the second pn junction layer 215 having a smaller band gap (e.g., E_{g}=1.42 eV), such that a photon having an energy of 1.42 eV<hν<1.9 eV is allowed to pass through the first pn junction layer 213 but is absorbed by the second pn junction layer 215. It is possible to realize higher light conversion efficiency by increasing the number of stacking.

The transparent conductive film used in the photovoltaic cell is required to exhibit excellent light transmittance, electrical conductivity, and light trapping efficiency. In particular, in the case of the tandem thin film photovoltaic cell, the transparent conductive film is required to show high light transmittance and a high haze value in a wide wavelength band from 350 to 1200 nm. In addition, the transparent conductive film is also required to withstand hydrogen plasma.

The transparent conductive film of tin oxide (SnO₂), which is generally used as a main ingredient thereof, has low light transmittance in a long wavelength range (of 900 nm or more), thereby resulting in a photovoltaic cell having low light conversion efficiency, and is deteriorated by hydrogen plasma in the coating process of the transparent conductive film.

Meanwhile, Indium Tin Oxide (ITO), which is generally used for existing transparent conductive films, has problems related to the continuously rising price of the main ingredient, indium (In), which is a rare element, the high reducibility of indium in the hydrogen plasma process and resultant chemical instability, and the like.

Therefore, studies are underway for the development of a transparent conductive film that can replace the transparent film including SnO₂ or ITO as a main ingredient. Zinc oxide (ZnO) is a material that is recently gaining attention as an ideal material. Since zinc oxide can be easily doped and has a narrow conductivity band, it is easy to control the electrical-optical properties of zinc oxide depending on the type of the dopant. In addition, the transparent conductive film having zinc oxide as a main ingredient is stable in the hydrogen plasma process, can be fabricated at a low cost, and exhibits high light transmittance and high electrical conductivity.

However, zinc oxide has a fatal defect in that moisture resistance is inferior, which can lead to decreased electrical conductivity as time passes, thereby degrading the performance and reducing the lifetime of the photovoltaic cell. Meanwhile, when the photovoltaic cell is placed or used under a high-humidity condition, alkaline ions, such as sodium ions (Na⁺), are eluted from inside the transparent substrate of the photovoltaic cell, thereby weakening the surface of the transparent substrate and making the surface of the transparent substrate hazy.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a photovoltaic cell substrate, which has light transmittance and haze characteristics applicable to a tandem thin film photovoltaic cell, is able to stably endure a plasma process, and has excellent moisture resistance.

Also provided is a photovoltaic cell substrate having high light conversion efficiency.

In an aspect of the present invention, the photovoltaic cell substrate includes a transparent substrate; a transparent conductive film formed over the transparent substrate, the transparent conductive film made of zinc oxide doped with a dopant; a protective film formed over the transparent conductive film; and an elution-preventive film formed between the transparent substrate and the transparent conductive film. The elution-preventive film prevents elution from inside the transparent substrate.

According to an exemplary embodiment of the invention, the photovoltaic cell substrate may further include an antireflection film formed between the transparent substrate and the elution-protective film.

As set forth above, the photovoltaic cell substrate of the present invention includes the transparent conductive film which is made of the doped zinc oxide, the protective film, and the elution-preventive film. Accordingly, the photovoltaic cell substrate has advantageous effects, such as excellent light transmittance and haze characteristics suitable for a tandem thin film photovoltaic cell and excellent moisture resistance, thereby improving the performance and increasing the lifetime of the photovoltaic cell.

In addition, the photovoltaic cell substrate of the present invention includes the antireflection film formed between the transparent substrate and the elution-protective film. The antireflection film can advantageously raise light transmittance, and thus improve the photoelectric conversion efficiency of the photovoltaic cell by preventing light from being reflected from the surface of the transparent substrate.

The methods and apparatuses of the present invention have other features and advantages which will be apparent from, or are set forth in more detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a cross-sectional view showing the structure of a photovoltaic cell using amorphous silicon as a light-absorbing layer in the related art;

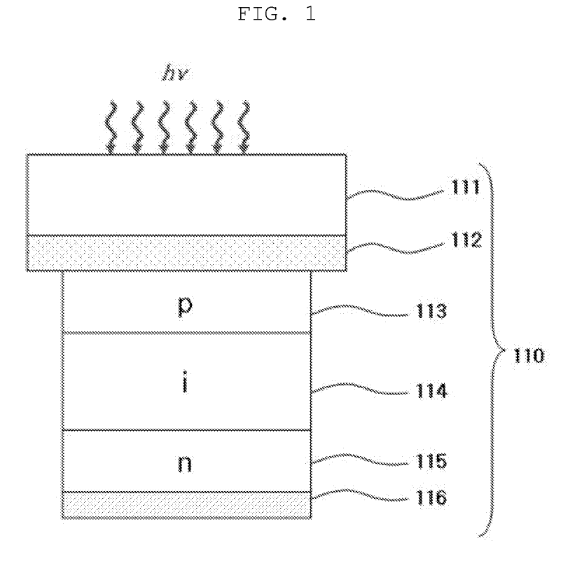

FIG. 2 is a cross-sectional view showing the structure of a tandem photovoltaic cell of the related art; and

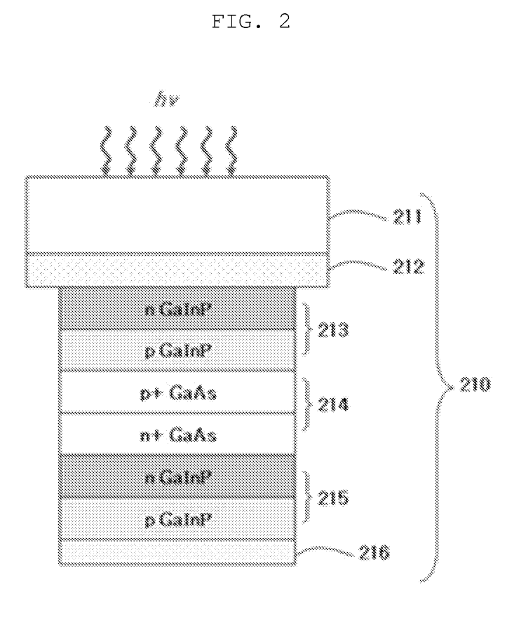

FIG. 3 is a cross-sectional view showing the structure of a photovoltaic cell substrate according to an exemplary embodiment of the invention.

### DETAILED DESCRIPTION OF THE INVENTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments that may be included within the spirit and scope of the invention as defined by the appended claims.

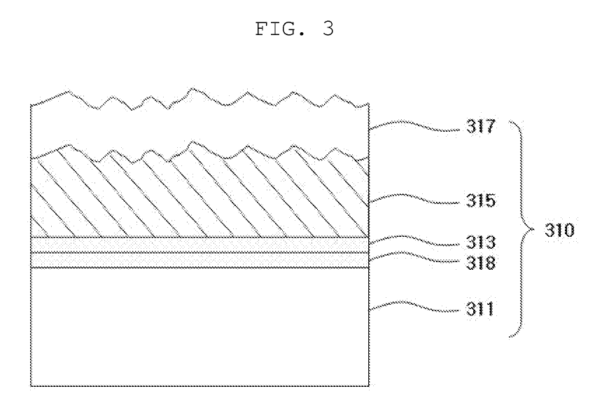

FIG. 3 is a cross-sectional view showing the structure of a photovoltaic cell substrate according to an exemplary embodiment of the invention.

As shown in the figure, the photovoltaic cell substrate 310 according to an exemplary embodiment of the invention includes a transparent substrate 311, an elution preventive film 313, a transparent conductive film 315, and a protective film 317.

The transparent substrate 311 serves to protect the photovoltaic cell, and can have an iron content of 0.06% or less, a thickness of 5 mm or less, and a light transmittance of 90% or more. In another example, the transparent substrate 311 can be a heat curing or Ultraviolet (UV) curing organic substrate, which is generally made of a polymer-based material. Examples of the polymer-based material may include Polyethylene Terephthalate (PET), acryl, Polycarbonate (PC), Urethane Acrylate (UA), polyester, Epoxy Acrylate (EA), brominate acrylate, Polyvinyl Chloride (PVC), and the like.

The elution preventive film 313 is formed over the transparent substrate 311, and serves to prevent elution from inside the transparent substrate 311. For example, if the transparent substrate 311 is made of glass, the elution preventive film 313 prevents the elution of alkaline ions, such as sodium ions (Na⁺). The elution preventive film 313 can be a silicon oxide (SiO₂) coating film that has a thickness of about 20 nm.

The transparent conductive film 315 conducts an electrical current generated by photoelectric conversion, and is made of a material that has high electric conductivity and high light transmittance. Preferably, the transparent conductive film 315 has good photoelectric conversion efficiency if the surface resistance thereof is 15Ω/□ or less. The surface resistance of the transparent conductive film 315 depends on the thickness thereof, as presented in Table 1 below.

TABLE 1

| | | | |
|---|---|---|---|
| Film thickness (nm) | 450 | 700 | 900 |
| Surface resistance (Ω/□) | 14 | 9 | 7 |

As presented in Table 1 above, if the thickness of the transparent conductive film 315 is 450 nm or more, the surface resistance of the transparent conductive film 315 is normally 15Ω/□ or less. If the thickness of the transparent conductive film 315 is 900 nm or less, the surface resistance is reduced, while as a drawback, the cost of forming the conductive film is increased.

Zinc oxide (ZnO) is used in the transparent conductive film 315. It is easy to control the electrical-optical properties of zinc oxide depending on the kind of dopant, since it can be easily doped and has a narrow conductivity band. Since the electrical properties of zinc oxide itself are substantially the same as those of an insulator, zinc oxide has to be given electrical conductivity by doping it with a dopant using a plasma process. However, if the content of the dopant is 15% by weight or more, crystallinity is degraded, and thus, the size of crystal grains of the transparent conductive film 315 decreases.

Therefore, it is preferred that the transparent conductive film 315 contain a dopant at an amount ranging from 0.1% to 15% by weight and have a thickness ranging from 450 nm to 900 nm. Here, the dopant can be one selected from among fluorine (F), aluminum (Al), gallium (Ga), and boron (B).

The transparent conductive film 315 can be formed by Plasma Enhanced Chemical Vapor Deposition (PECVD), Chemical Vapor Deposition (CVD), Low Pressure CVD (LPCVD), Atmospheric Pressure CVD (APCVD), sputtering, or the like.

The protective film 317 is formed over the transparent conductive film 314 in order to improve the moisture resistance of the transparent conductive film 315. Generally, the characteristics of zinc oxide, which is used as the main ingredient of the transparent conductive film 315, are degraded under a high-humidity condition. Accordingly, the protective film 317 is required to exhibit excellent electrical conductivity and light transmittance while protecting zinc oxide from moisture. For example, the protective film 317 has a thickness ranging from 15 nm to 25 nm, and can include SnO₂:F or Indium Tin Oxide (ITO).

In another aspect of the invention, the photovoltaic cell substrate 310 can also include an antireflection film 318.

The antireflection film 318 serves to prevent the reflection of external light. The antireflection film 318 can be a single layer film having an optical thickness of, for example, ¼ of a wavelength of the incident light. The single layer film can be a thin film of transparent fluorine-based polymer resin, magnesium fluoride, silicon-based resin, silicon oxide, or the like. In addition, the antireflection film 318 can have a multilayer structure that includes two or more layers of thin films having different refractive indices, which can be made of an inorganic compound, such as metal oxide, fluoride, silicide, boride, carbide, nitride, sulfide, or the like, or an organic compound, such as silicon-based resin, acrylic resin, fluorine-based resin, or the like.

For example, the antireflection film 318 has a thickness ranging from 15 nm to 25 nm, and can include one material selected from among TiO₂, Nb₂O₅, Ta₂O₅, Ti₂O₃, Si₃N₄, and Ti₃O₅.

The foregoing descriptions of specific exemplary embodiments of the present invention have been presented for the purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A photovoltaic cell substrate comprising:
a transparent substrate;
a transparent conductive film formed over the transparent substrate, the transparent conductive film made of zinc oxide doped with a dopant; and
a protective film formed over the transparent conductive film.

2. The photovoltaic cell substrate according to claim 1, wherein the dopant has a content ranging from 0.1 to 15 percent by weight, and wherein the transparent conductive film has a thickness ranging from 450 nm to 900 nm.

3. The photovoltaic cell substrate according to claim 2, wherein the dopant comprises one selected from the group consisting of fluorine, aluminum, gallium, and boron.

4. The photovoltaic cell substrate according to claim 1, wherein the dopant comprises one selected from the group consisting of fluorine, aluminum, gallium, and boron.

5. The photovoltaic cell substrate according to claim 1, wherein the protective film comprises SnO₂.

6. The photovoltaic cell substrate according to claim 1, wherein the protective film has a thickness ranging from 15 nm to 25 nm, and includes SnO₂:F or indium tin oxide.

7. The photovoltaic cell substrate according to claim 1,
further comprising an elution-preventive film formed between the transparent substrate and the transparent conductive film, the elution-preventive film preventing elution from inside the transparent substrate.

8. The photovoltaic cell substrate according to claim 7, wherein the transparent substrate comprises a glass substrate, and wherein the elution-preventive film prevents alkaline ions from being eluted from inside the glass substrate.

9. The photovoltaic cell substrate according to claim 7, wherein the elution-preventive film comprises a silicon oxide (SiO₂) coating film.

10. The photovoltaic cell substrate according to claim 7, further comprising an antireflection film formed between the transparent substrate and the elution-preventive film.

11. The photovoltaic cell substrate according to claim 10, wherein the antireflection film has a thickness ranging from 15 nm to 25 nm, and comprises one material selected from the group consisting of TiO₂, Nb₂O₅, Ta₂O₅, Ti₂O₃, Si₃N₄, and Ti₃O₅.
